(19) United States
(12) Patent Application Publication
(10) Pub. No.: US 2026/0333572 A1
(43) Pub. Date: Oct. 22, 2026

(54) PRINTED CIRCUIT BOARD (PCB) VOIDING FOR CONNECTOR CONTACTS

(71) Applicant: Nvidia Corporation, Santa Clara, CA (US)

(72) Inventors: John NORTON, Houston, TX (US); Cong GAO, Pflugerville, TX (US); Biao HU, San Jose, CA (US)

(21) Appl. No.: 19/183,109

(22) Filed: Apr. 18, 2025

(51) Int. Cl. H05K 1/02; H05K 1/11; H05K 3/00; H05K 3/46

(52) U.S. Cl. CPC H05K 1/024; H05K 1/117; H05K 3/0047; H05K 3/4679; H05K 3/4697; H05K 2201/09381; H05K 2201/09418

(57) ABSTRACT

According to certain embodiments, a circuit board is provided. The circuit board includes a circuit board substrate; and a connection finger pad disposed on a first surface of the circuit board substrate. An air void is disposed within the circuit board substrate that is aligned with at least a portion of the connection finger pad. In certain embodiments, a method for fabricating the circuit board is provided.

### BACKGROUND

In various scenarios, a pluggable card may include a printed circuit board (PCB) having connection pads. The pluggable card may be inserted into connector having connector pins that, when the pluggable card is inserted into the connector, are in electrical communication with respective connector pads of the PCB. However, when high-speed electrical signals are communicated between a connector pin and a connector pad, the signal integrity of the communicated signal can suffer. Accordingly, a need exists for providing improved signal integrity communications between connector pads of a pluggable card and connector pins of a connector configured to receive a pluggable card.

### GENERAL DESCRIPTION

In various computing environments, a pluggable card may be used to provide various functionality. For example, a pluggable card may host one or more central processing units (CPUs), graphic processing units (GPUs), parallel processing units (PPUs), data processing units (DPUs), quantum processing units (QPUs), switches, and/or potions thereof. In another example, a pluggable card may host computer-readable memory. In some embodiments, the circuit board is part of a peripheral component interconnect express (PCIe) component of a computing environment. For example, the circuit board may be a PCB that hosts a PCIe switch and/or the like. In some scenarios, the connectors into which a pluggable card may be inserted may be part of a datacenter tray.

Datacenters often include a plurality of server racks having respective pluralities of trays mounted therein. The trays may include carious components that communicate with one another via a fast and robust communication infrastructure. For example, optical interconnects may enable communication between various trays and/or server racks. In at least one example embodiment, the optical interconnect is part of a datacenter that corresponds to a collection of network devices, such as network switches (e.g., Ethernet switches, IP routers, multiservice platforms, various transmission network elements, legacy communication equipment, or in any other suitable communication system) connected with a collection of servers or compute nodes. For example, various components of a datacenter may be configured to communicate with each other at high-speed. For example, high-speed signals may be characterized by frequencies greater than 100 MHz. Thus, at least some of the contact pads of a pluggable card may be configured to receive high-speed signals.

A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated Circuits (ASICs), and in some implementations also bus interconnects. The datacenter may adhere to a networking topology (e.g., a hierarchal networking topology), such as a fat tree topology, a Slim Fly topology, a Dragonfly topology, and/or the like. The datacenter routes traffic amongst the network switches and servers therein, and at least one layer of the topology in the datacenter is coupled to the communication network to allow networking traffic to flow between the datacenter and the network device(s).

In some embodiments, optical interconnects include transceivers used to connect network-connected devices (e.g., remote client switches, network adapters such as Network Interface controllers (NICs) and Host Channel Adapters (HCAs), Smart-NICs (NICs having embedded CPUs), network-enabled Graphics Processing Units (GPUs), and the like). The terms “network-connected device” and “network device” are used interchangeably herein. In certain embodiments, an optical interconnect includes a substrate, one or more optical waveguides, one or more first micro-lenses, one or more second micro-lenses, and first and second mechanical fixtures.

A “node” as described herein may refer to a network switch to which a plurality of computer processing units (CPUs), graphical processing units (GPUs), data processing units (DPUs), or memory media are connected in an arbitrary number. The network switch may communicate with other network switches of the same kind to which the same processor and memory units may be connected. However, in other implementations, “node” may also refer to a processor which may be responsible for communication with all other nodes in the network or subnetwork.

An “optical fiber” as described herein can refer to a single optical fiber (e.g., including a core and a cladding) to provide unidirectional optical communication, can refer to a bidirectional pair of optical fibers (e.g., each including a core and a cladding) to provide both transmit and receive communications in an optical network, or can refer to a multi-core fiber, such that a single cladding could encapsulate a plurality of single-mode cores. Optical fibers can extend contiguously and uninterrupted between node or send/receive pairs (e.g., via pass-through connections) or include two or more fibers connected via fiber-to-fiber connections such that the fibers function or perform as a single fiber.

Silicon Photonics (SiP) is a technology that enables optical systems to be manufactured using silicon processes with silicon as the optical medium. Various optical components, such as interconnects and signal processing components, may be fabricated and integrated in a single SiP device. Some SiP devices are fabricated on a silica substrate or over a silica layer on a silicon substrate, a technology that is often referred to as Silicon on Insulator (SOI). In certain optical systems, a SiP device is attached to an external device to facilitate optical communications. However, it is generally difficult to accurately align light signals on the SiP with an external device that receives the light.

In certain optical systems, a SiP device is attached to an external device to facilitate optical communications. For example, the system includes one or more waveguides that carry light signals to and/or from optical chips. Examples of optical chips that can be included on the device include, but are not limited to, one or more components selected from a group consisting of facets through which light signals can enter and/or exit a waveguide, entry/exit ports through which light signals can enter and/or exit a waveguide from above or below the device, multiplexers for combining multiple light signals onto a single waveguide, demultiplexers for separating multiple light signals such that different light signals are received on different waveguides, optical couplers, optical switches, lasers that act as a source of a light signal, amplifiers for amplifying the intensity of a light signal, attenuators for attenuating the intensity of a light signal, modulators for modulating a signal onto a light signal, modulators that convert a light signal to an electrical signal, and vias that provide an optical pathway for a light signal traveling through the device. Additionally, the device can optionally, include electrical components. For instance, the device can include electrical connections for applying a potential or current to a waveguide, controlling active optical components, such as modulators, for example, and/or for controlling other components on the optical device.

The connection finger pad is characterized by a finger length that is at least as long as a wipe length of the connection finger pad which causes an electrical stub effect in which a λ/4 (wherein λ is a wavelength characterizing a signal) resonance degrades the system signal integrity (roll off of insertion loss). Typically, this was addressed by reducing the length of the gold finger wipe or stub, which directly relates to the impact on signal integrity. However, system tolerances and deflections make a certain amount of wipe distance/stub required to maintain electrical connection and robustness of the mechanical connection. By creating a void within the PCB (e.g., within the circuit board substrate) by removing the dielectric underneath the portion of the finger that generates the stub, its impact on signal integrity is mitigated. This happens because the void reduces the capacitance around the stub and shifts the phase delay of the reflecting wave from the edge of the pad to the contact point. This pushes the resonance roll off frequency beyond the frequency of interest for the signal and allowing higher data rate through the interface.

Unlike other solutions to the resonance problem, this invention allows the interface to maintain the wipe distance and achieve higher data rates where otherwise wipe distance would have to be reduced (which negatively effects the electrical and mechanical connection between the circuit board (e.g., PCB, pluggable card) and the connector. Traditionally, PCIe cards have reduced wipe to achieve higher data rates and maintain backwards compatibility. However, the latest generation of cards in development (Gen7) can no longer reduce wipe because of unachievable tolerance and deflection requirements in the system. Currently the Peripheral Component Interconnect Special Interest Group (PCISIG) is looking for other options to achieve Gen7 signal integrity (SI) targets while maintaining wipe distance. Creating an air pocket underneath and/or aligned with high-speed signal pads on a plug-in finger edge interface reduces capacitance and improves signal integrity while maintaining the necessary wipe length for a robust connection.

In various embodiments, circuit boards having reduced capacitance in the vicinity of high-speed electrical channels are provided. For example, a circuit board (e.g., a PCB, pluggable PCIe component, and/or the like) may include a circuit board substrate and a connection finger pad disposed on a first surface of the circuit board substate and configured to provide a high-speed communication channel between a connector pin of a connector and various components of the circuit board. An air void is disposed within the circuit board substrate (e.g., within one or more dielectric layers of the circuit board substrate) and is aligned with at least a portion of the connection finger pad. The presence of the air void between the connection finger pad and any conductive elements formed on a second surface of the circuit board substrate results in a reduced capacitance of the circuit board at the connection finger pad (compared to if the air voids were filled with dielectric material). This results in improved signal integrity of high-speed electrical signals communicated therethrough.

According to an aspect of the present disclosure, a circuit board is provided. The circuit board includes a circuit board substrate; and a connection finger pad disposed on a first surface of the circuit board substrate. An air void is disposed within the circuit board substrate that is aligned with at least a portion of the connection finger pad.

In an example embodiment, the circuit board comprises a dielectric layer and the air void is disposed within the dielectric layer.

In an example embodiment, the connection finger pad is characterized by a finger length that is at least as long as a wipe length of the connection finger pad, and the air void has a void length that is within half a millimeter of the wipe length.

In an example embodiment, the void length is substantially equal to the wipe length.

In an example embodiment, the void length is substantially equal to half the finger length.

In an example embodiment, the connection finger pad is characterized by a finger width and the air void is characterized by a void width and the finger width is substantially equal to the void width.

In an example, embodiment, the air void is characterized by a void height and the void height is greater than zero and no more than 0.8 mm.

In an example embodiment, wherein the void height is at least 0.4 mm.

In an example embodiment, the circuit board further includes a conductive component disposed on a second surface of the circuit board substrate, the first surface opposite the second surface, and the air void is disposed between the connection finger pad and the conductive component.

In an example embodiment, the connection finger pad is one of a plurality of connection finger pads and the air void is one of a plurality of air voids and respective air voids are aligned with respective connection finger pads.

In an example embodiment, each of the plurality of connection finger pads is configured for communicating electrical signals characterized by frequencies of at least 100 MHz.

In an example embodiment, the circuit board further includes one or more conductive pads configured for communicating electrical signals characterized by frequencies less than 100 MHz.

In an example embodiment, the air void is a first air void and the circuit board further comprises a second air void, the first air void and the second air void aligned with one another between the first surface and a second surface of the circuit board.

According to another aspect, networking card is provided. The networking card includes a circuit board having a plug-in finger edge interface. The plug-in finger edge interface includes one or more connection finger pads formed on a circuit board substrate of the circuit board. One or more air voids are disposed within the circuit board substrate and each of the one or more air voids are aligned with at least a portion of a respective connection finger pad of the one or more connection finger pads.

In an example embodiment, the networking card is a PCIe card.

According to another aspect, a method for fabricating a circuit board is provided. In an example embodiment, the method includes fabricating a circuit board substrate such that the circuit board substrate comprises an air void within the circuit board substrate; and patterning a conductive material on a first surface of the circuit board substrate to form a connection finger pad that is aligned with the air void.

In an example embodiment, fabricating the circuit board substrate includes preparing a plurality of individual layers of the substrate, the plurality of individual layers comprising at least one air void layer and at least one void-free layer; and drilling a cavity or a hole in each of the air void layer of the plurality of individual layers.

In an example embodiment, the cavity or hole is drilled using laser drilling.

In an example embodiment, the plurality of individual layers includes respective copper sub-layers and dielectric sub-layers and a copper sub-layer of an air void edge layer is used as a laser stopper layer during the laser drilling.

In an example embodiment, fabricating the circuit board substrate further includes sequentially laminating air void layers of the plurality of individual layers to form one or more substrate portions having respective openings formed therein.

In an example embodiment, fabricating the circuit board substrate further comprises laminating the one or more substrate portions and the at least one void-free layer to form the circuit board substrate having one or more air voids defined therein.

### BRIEF DESCRIPTION OF THE SEVERAL VIEWS OF THE DRAWINGS

Reference will now be made to the accompanying drawings, which are not necessarily drawn to scale, and wherein:

FIG. 1A provides a schematic cross-sectional diagram of an example circuit board taken in a plane perpendicular to a surface of the circuit board substrate, in accordance with certain embodiments;

FIG. 1B provides a schematic cross-sectional diagram of another example circuit board taken in a plane perpendicular to a surface of the circuit board substrate, in accordance with certain embodiments;

FIG. 1C provides schematic views of an example circuit board including air voids, in accordance with certain embodiments;

FIG. 1D provides a schematic cross-sectional diagram of an example circuit board taken in a plane perpendicular to a surface of the circuit board substrate, in accordance with certain embodiments;

FIG. 2A provides a top view of an example circuit board, in accordance with certain embodiments;

FIG. 2B provides a cross-sectional view of the example circuit board shown in FIG. 2A taken in a plane parallel to a surface of the circuit board substrate, in accordance with certain embodiments;

FIG. 2C provides a top view of another example circuit board, in accordance with certain embodiments;

FIGS. 3A, 3B, and 3C each provide plots comparing the functioning of an example embodiment to a conventional circuit board;

FIG. 4 provides a flowchart illustrating various processes and/or procedures for fabricating a circuit board, in accordance with certain embodiment;

FIG. 5 provides a flowchart illustrating various processes and/or procedures for fabricating a circuit board substrate, in accordance with certain embodiments;

FIGS. 5A-5D illustrate schematic cross-sections of a circuit board substrate at various stages of fabrication, in accordance with certain embodiments;

FIG. 6 provides a block diagram of an example system that may include one or more circuit boards including air voids therein aligned with connection finger pads of high-speed electrical channels, according to certain embodiments;

FIG. 7 provides a schematic diagram of an example datacenter that may include one or more circuit boards according to certain embodiments;

FIG. 8 provides a block diagram that schematically illustrates a computing system that may include one or more optical interconnects of various embodiments;

FIG. 9 illustrates an example computing environment, in accordance with at least one embodiment; and

FIG. 10 illustrates another example computer system that may include optical interconnects, according to at least one embodiment.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

Various embodiments provide a circuit board of a pluggable card and/or the like having one or more connector pads (e.g., connection finger pads) configured to place the circuit board into electrical communication with respective connector pins of a connector. In various embodiments, the circuit board is configured to enable electrical communication between respective connector pins and respective connection finger pads with improved signal integrity and/or high bandwidth. For example, the circuit board substrate, on which the connection finger pads are formed, may include air voids in one or more dielectric layers thereof. These air voids decrease a capacitance of the circuit board in the vicinity of the connection finger pads, compared to conventional circuit boards.

For example, when the circuit board exhibits a higher capacitance in the vicinity of the connection finger pads, an electrical signal communicated via the electrical channel including the connection finger pad becomes distorted (e.g., by resonances influenced by the capacitance). In other words, as a result of resonances within the circuit board affecting the electrical channel, the signal integrity of electrical signals communicated via the electrical channel is decreased. This in turn limits the bandwidth of the electrical channel. Therefore, technical problems exist regarding how to place circuit boards, such as pluggable cards (e.g., Add-In Card (AIC)), into electrical communication with a connector.

Various embodiments provide technical solutions to these technical challenges. For example, air voids are formed in one or more dielectric layers of the circuit board substrate on which the connection finger pads are formed. In various embodiments, the air voids are aligned with the connection finger pads. This reduces the capacitance of the circuit board in the vicinity of the connection finger pads. The reduced capacitance changes the frequency of the resonance and/or reduces the coupling strength of the resonance to the electrical channel including the connection finger pads. As a result, the signal integrity of electrical signals communicated via the electrical channel including the connection finger pad is maintained and the bandwidth of communications via the electrical channel may be increased (e.g., compared to conventional pluggable cards). Various embodiments provide circuit boards (e.g., PCBs) including air voids (e.g., in dielectric layers of the circuit board substrates) in the vicinity of connection finger pads formed on the circuit board. Various embodiments provide methods for fabricating circuit boards including air voids (e.g., in dielectric layers of the circuit board substrates) in the vicinity of connection finger pads formed on the circuit board. Therefore, various embodiments provide technical improvements to the fields of circuit boards, PCBs, pluggable cards, and/or the like.

### Example Circuit Board

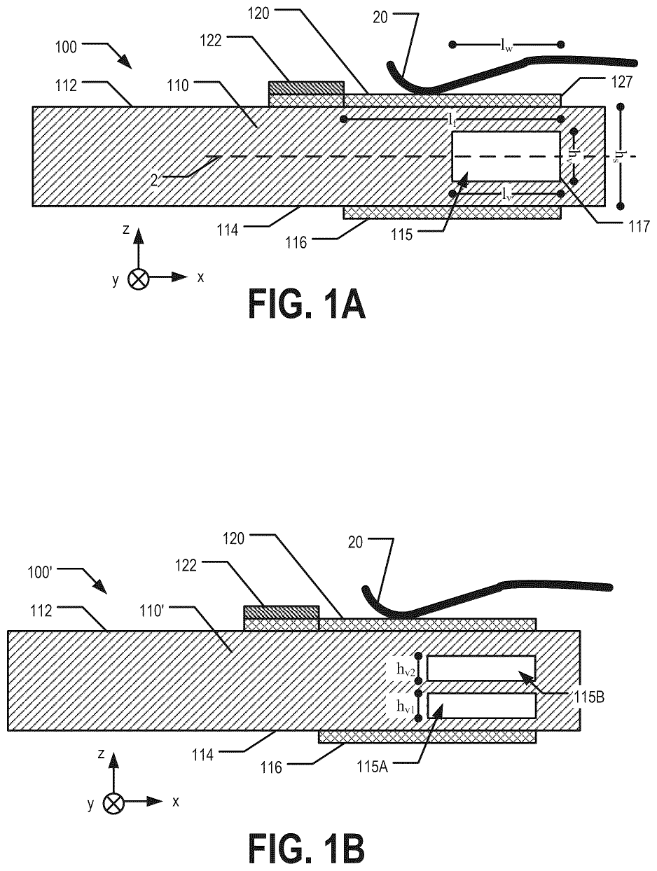

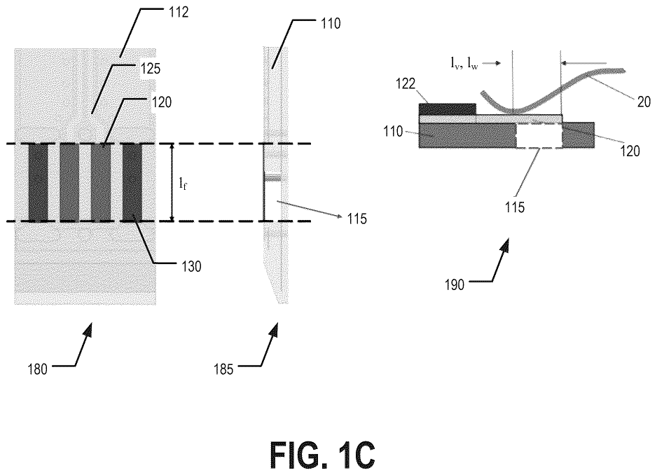

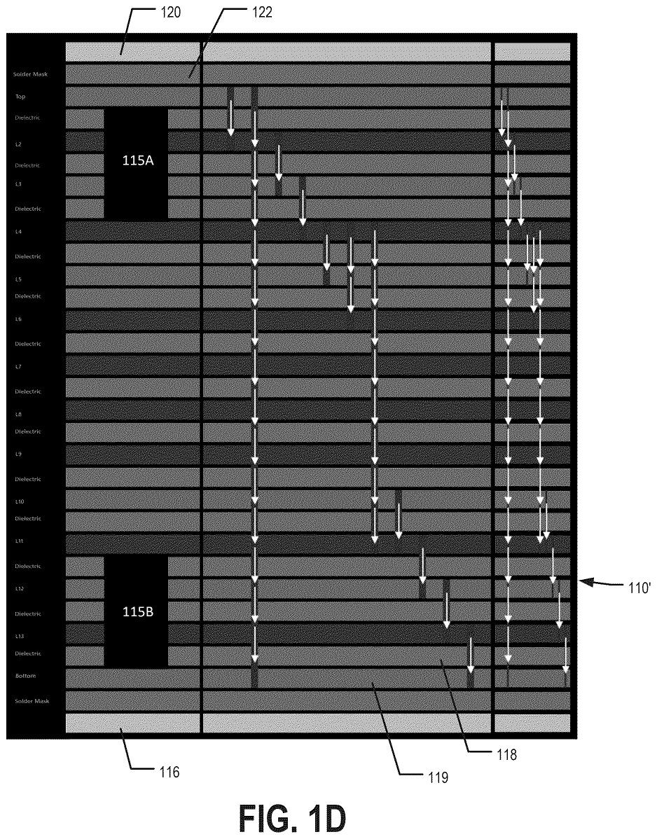

FIG. 1A illustrates a cross-section of a circuit board 100 taken in a plane that is perpendicular to a first surface 112 of the circuit board substrate 110. The circuit board 100 may be a printed circuit board (PCB), pluggable card, and/or the like

In various embodiments, the circuit board 100 comprises a circuit board substrate 110 and one or more connection finger pads 120 formed on a first surface 112 of the circuit board substrate 110. The circuit board 100 may further include a conductive element 116 on a second surface 114 of the circuit board substrate 110. In some embodiments, the conductive element 116 is aligned, at least in part with at least one connection finger pad 120. As used herein, an element is aligned with a connection finger pad 120 if, for at least one point on the connection finger pad 120, a line perpendicular to the first surface 112 of the circuit board substrate 110 that intersects the connection finger pad 120 also intersects the element.

In various embodiments, the circuit board substrate 110 includes an air void 115. In various embodiments, the air void 115 is enclosed within the circuit board substrate 110. For example, the first surface 112 and the second surface 114 of the circuit board substrate may be surfaces including a dielectric material and/or the like. The air void 115 may be enclosed between the first surface 112 and the second surface 114. In various embodiments, the air void 115 is formed in one or more dielectric layers of the circuit board substrate 110. In various embodiments, the air void 115 is a distance of 0.1 to 0.8 mm from the first surface 112 in a direction that is perpendicular to the first surface 112. In various embodiments, the air void 115 is a distance of 0.1 to 0.8 from the second surface 114 in a direction that is perpendicular to the first surface 112. In certain embodiments, the air void is equidistant from the first surface 112 and the second surface 114.

FIG. 1B illustrates a cross-sectional view of at least a portion of an example circuit board 100′ where the cross-section is taken in a plane perpendicular to the first surface 112 of the circuit board substrate 110'. The circuit board substrate 110′ includes multiple air voids 115A, 115B that are aligned with one another in a direction perpendicular to the first surface 112, in accordance with various embodiments.

FIG. 1C illustrates a top view 180 of a portion of an example circuit board 100 and a slice 185 of the example circuit board illustrating the presence of the air void 115 aligned with connection finger pad 120. The first surface 112 is shown in the top view 180 as semi-transparent such that circuitry and/or leads 125 (e.g., which may be disposed on an interior layer of the circuit board substrate 110) of the electrical channel including the connection finger pad 120 is/are partially visible. Low-speed connection pads 130 are also present on the first surface 112. In the illustrated embodiment, the low-speed connection pads 130 are ground connection pads (e.g., pads configured for a generally stable and/or non-oscillating signal).

FIG. 1C further includes a cross-sectional view 190 of the example circuit board 100 taken in a plane perpendicular to the first surface 112 of the circuit board substrate 110. The cross-sectional view 190 illustrates an air void being aligned with a connection finger pad 120 and the interaction between a connector pin 20 and the connection finger pad 120.

FIG. 1D illustrates a cross-sectional view of an example circuit board 100′ having a circuit board substrate 110′ comprising a plurality of alternating dielectric layers 118 and conducting layers 119 (e.g., signal planes, power planes, ground planes, and routing layers). For example, the circuit board substrate is formed by alternating dielectric layers 118 and conducting layers 119. Solder masks 122 may be disposed on the either side/end of the stack of alternating dielectric layers 118 and conducting layers 119. Patterned metal layers (e.g., including the connection finger pad 120 and/or the conductive element 116) are disposed on the surfaces of the circuit board substrate 110′. The vertical arrows illustrate the direction of drilling for fabricating vias and/or holes that enable connections between various conducting layers 119 of the circuit board such that an electrical channel may be partially disposed on various conducting layers 119 of the circuit board 100′, as appropriate for the application.

As shown in FIG. 1D, the circuit board substrate 110′ may include multiple air voids 115A, 115B that are aligned with one another. Each air void is formed through at least one dielectric layer 118. In various embodiments, an air void 115 (e.g., 115A, 115B) may be formed through a plurality of dielectric layers 118 and one or more conducting layers 119.

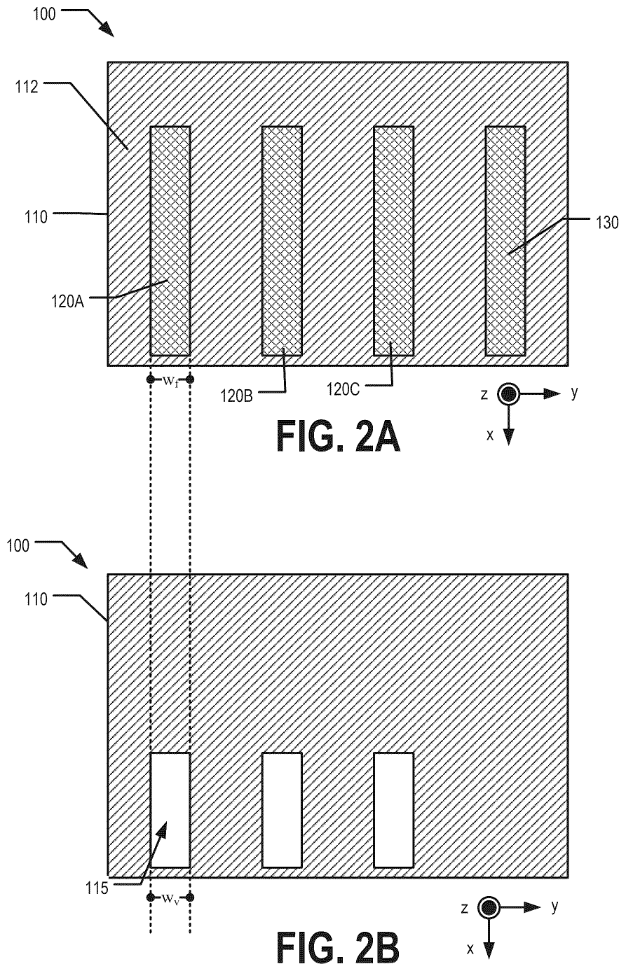

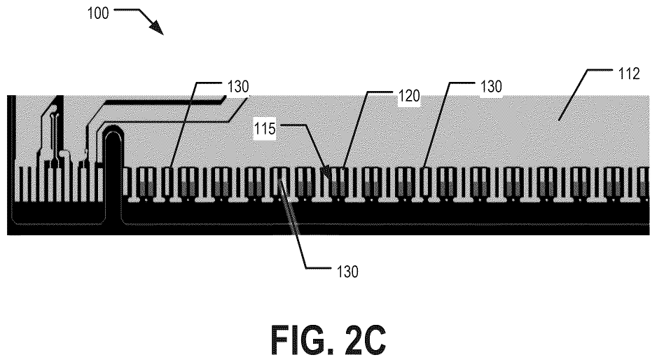

FIG. 2A illustrates a top view of at least a portion of the circuit board 100 illustrating that the circuit board 100 includes a plurality of connection finger pads (e.g., 120A, 120B, 120C). Each of the connection finger pads 120 are configured to communicate with a respective connector pin 20 via a high-speed electrical signal. The circuit board 100 may further include one or more low-speed connection pads 130. For example, the low-speed connection pads 130 may be configured to communicate with a respective connector pin via a low-speed electrical signal.

FIG. 2B illustrates a cross-sectional view of at least a portion of the circuit board 100 taken in a plane parallel to the first surface 112 of the circuit board substrate 110 along line 2 shown in FIG. 1A. As can be seen by comparing FIGS. 2A and 2B, air voids 115 are aligned with each of the connection finger pads 120. However, an air void 115 is not aligned with the low-speed connection pad 130, in the illustrated embodiment.

In various embodiments, the circuit board 100 is configured to be placed into electrical communication with a connector such that connector pins 20 of the connector are in electrical communication with respective connection finger pads 120 (and possibly low-speed connection pad(s) 130). As the circuit board 100 is pushed into the connector, a connector pin 20 scrapes or wipes along a respective connection finger pad. The circuit board 100 is configured such that the connector pin 20 scrapes or wipes along the respective connection finger pad 120 for a wipe length l_{w}. As used herein, the term length refers to a distance in a direction that the circuit board 100 is moved to engage the circuit board 100 with a connector including connector pin 20.

In some embodiments, a solder mask 122 may cover a portion of a connection finger pad 120. The exposed portion of the connection finger pad 120 is a finger length l_{f}. The finger length is longer than the wipe length (e.g., l_{f}>l_{w}). In various embodiments, the air void 115 is characterized by a void length lᵥ. In various embodiments, the void length is less than the finger length (e.g., l_{f}>lᵥ). In some embodiments, the wipe length and/or the void length is approximately half the finger length (e.g., l_{f}=2l_{w} and/or l_{f}=2lᵥ). In some embodiments, the void length is substantially equal to the wipe length (e.g., lᵥ=l_{w}). For example, the void length may be within half a millimeter of the wipe length (e.g., l_{w}−0.5 mm≤lᵥ≤l_{w}+0.5 mm). In an example embodiment, the wipe length and/or the void length is in a range of 1.1 mm to 1.4 mm (e.g., approximately 1.25 mm). In an example embedment, the finger length is in a range of 2 mm to 3 mm.

In various embodiments, the air void 115 is characterized by a void height hᵥ in a direction that is perpendicular the first surface 112 of the circuit board substrate 110. In various embodiments, the void height is greater than zero and no more than 1 mm. For example, the void height may be no more than 0.8 mm, in an example embodiment. In some embodiments, the void height is in a range of 0.4 to 0.8 mm (e.g., 0.4 mm≤hᵥ≤0.8 mm). In various embodiments where the circuit board substrate 110′ includes multiple air voids that are aligned with one another (e.g., such as air void 115A and air void 115B shown in FIG. 1B), the sum of the heights of the multiple voids is no more than 1 mm (e.g., hᵥ₁+hᵥ₂<1 mm). For example, the sum of the heights of the multiple voids may be in a range of 0.4 to 0.8 mm. In various embodiments, the circuit board substrate 110 is characterized by a substrate height hₛ and the substrate height is greater than the void height. In some embodiments, the substrate height is 0.2 to 1.6 mm greater than the void height. For example, the substrate height may be 1 mm greater than the void height (e.g., hₛ=hᵥ+1mm), in an example embodiment.

In various embodiments, a connection finger pad 120 is characterized by a finger width w_{f} in a plane parallel to the first surface 112 of the circuit board substrate 110. In various embodiments, the air void 115 is characterized by a void width wᵥ in a plane parallel to the first surface 112 of the circuit board substrate 110. In certain embodiments, the void width is substantially equal to the finger width (e.g., wᵥ=w_{f}).

In an example embodiment, the leading edge 127 of the connection finger pad 120 is aligned with the leading edge 117 of the air void 115. In some embodiments, the air void 115 is completely aligned with the connection finger pad 120 such that for any point within the air void 115, a line perpendicular to the first surface 112 that intersects the point also intersects the corresponding connection finger pad 120.

By positioning the air void 115 within the circuit board substrate 110 such that the air void 115 is disposed between the connection finger pad 120 and the conductive element 116 disposed on the second surface 114 of the circuit board substrate 110, the capacitance of the circuit board in the vicinity of the connection finger pad 120 is reduced.

FIG. 2C provides a top view of a portion of a circuit board 100 comprising a plurality of connection finger pads 120 and a plurality of low-speed connection pads 130. The shadowing under the connection finger pads 120 represents the presence of an air void aligned with the connection finger pad 120 (e.g., the leading edge 127 of the connection finger pad 120 may be aligned with the leading edge 117 of the air void 115). In this illustrate example embodiment, air voids are not present/aligned with the low-speed connection pads 130.

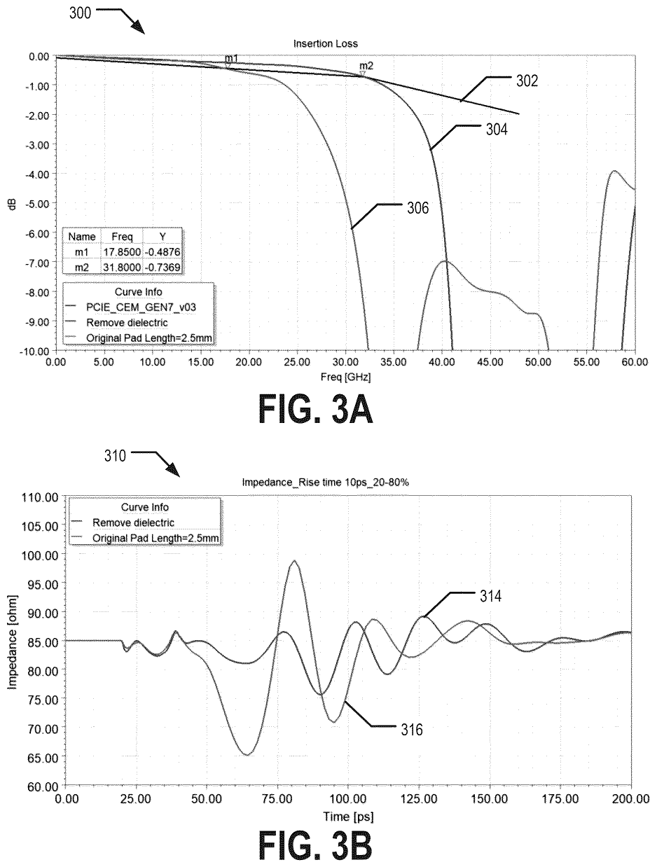

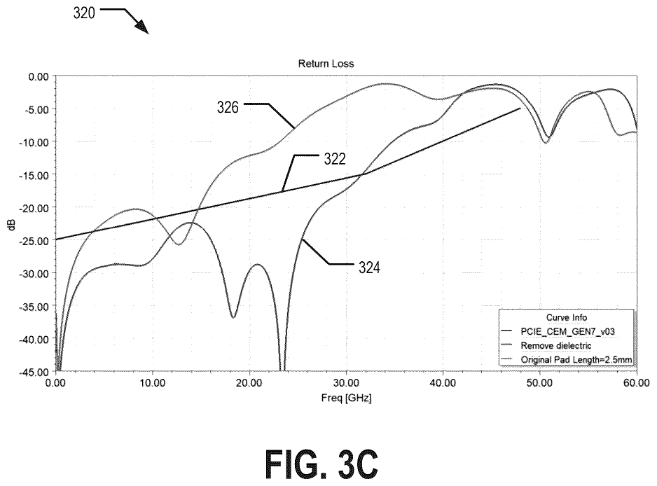

FIG. 3A provides a plot 300 that illustrates simulated results of the insertion loss for an electrical signal communicated between a connection finger pad 120 and a connector pin 20 as a function of a frequency that characterizes the electrical signal for a goal peripheral component interconnect express (PCIe) communication channel 302, an example embodiment where the circuit board substrate 110 includes an air void 304, and a conventional circuit board 306. As shown by the insertion loss of the conventional circuit board 306, the insertion loss increases significantly for electrical signals characterized by frequencies greater than about 20-25 MHz. The insertion loss of the example embodiment 304 maintains low insertion loss for electrical signals characterized by frequencies of 35 MHz, for example.

FIG. 3B provides a plot 310 that illustrates simulated results of the impedance as a function of time for a communication channel of an example embodiment 314 (e.g., where an air void 115 is aligned with the connection finger pad 120 of the communication channel) and for a communication channel of a conventional circuit board 316. The impedance of the communication channel of the example embodiment 314 is more constant in time and/or varies less with time compared to the impedance of the communication channel of the conventional circuit board 316.

FIG. 3C provides a plot 320 that illustrates simulated results of the return loss for an electrical signal communicated between a connection finger pad 120 and a connector pin 20 as a function of a frequency that characterizes the electrical signal for a goal PCIe communication channel 322, a communication channel of an example embodiment (e.g., where an air void 115 is aligned with the connection finger pad 120 of the communication channel) 314, and a communication channel of a conventional circuit board 326.

### Example Method for Fabricating a Circuit Board

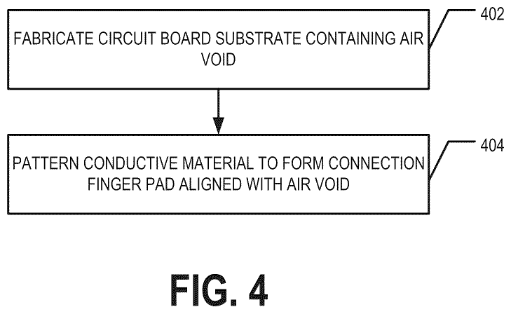

FIG. 4 provides a flowchart illustrating various processes and/or procedures for fabricating a circuit board 100, 100'. Starting at block 402, a circuit board substrate 110, 110′ is fabricated that contains one or more air voids 115 therein. For example, the circuit board substrate may include a plurality of layers, including dielectric layers, one or more ground planes, electrical interposer layers (e.g., comprising electrically conductive traces and/or the like) and/or the like. The one or more dielectric layers may be formed so as to include one or more air voids. For example, a low flow resin process may be used to fabricate and/or form the circuit board substrate having one or more air voids formed in one or more dielectric layers thereof at locations corresponding to connection finger pads. For example, the air voids may be disposed in a resin system of the circuit board substrate 110, 110′.

At block 404, a conductive material (e.g., copper, gold, aluminum, and/or the like) is patterned to form connection finger pads 120 that are aligned with respective air voids 115. In some embodiments, the conductive material is deposited onto the first surface 112 of the circuit board substrate 110, 110′ and then patterned using a lift-off method, lithographic etch, and/or other patterning technique. In some embodiments, the conductive material is applied to the first surface 112 as a foil or layer and then patterned to form the connection finger pads 120. The conductive material may also be patterned to form any low-speed connection pads 130 of the circuit board, and/or other conductive pads or conductive surfaces of the circuit board.

In some embodiments, a conductive material (e.g., copper, gold, aluminum, and/or the like) is patterned on the second surface 114 of the circuit board substrate 110, 110′ to form one or more conductive elements 116. For example, the conductive elements 116 may be configured to protect the second surface 114 of the circuit board substrate 110, 110′ when the circuit board 100, 100′ is inserted and/or removed from a connector comprising connector pins 20, act as a ground contact, and/or the like.

In various embodiments, the circuit board substrate comprises a plurality of layers where each layer comprises a prepreg sublayer and at least one copper sublayer. The circuit board substrate is formed by laminating the plurality of layers together. In various embodiments, laser drilling technology is used to cavity the air voids within low flow prepreg before lamination of the layers of the circuit board substrate. In some embodiments, copper sub-layers of an air void edge layer is used as laser stopper (e.g., to stop the laser drilling and/or etching. The use of the copper sub-layer as a laser stopper enables the depth of air voids to be precisely controlled.

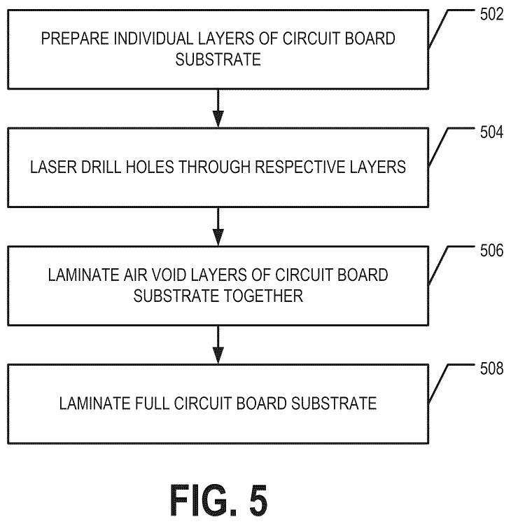

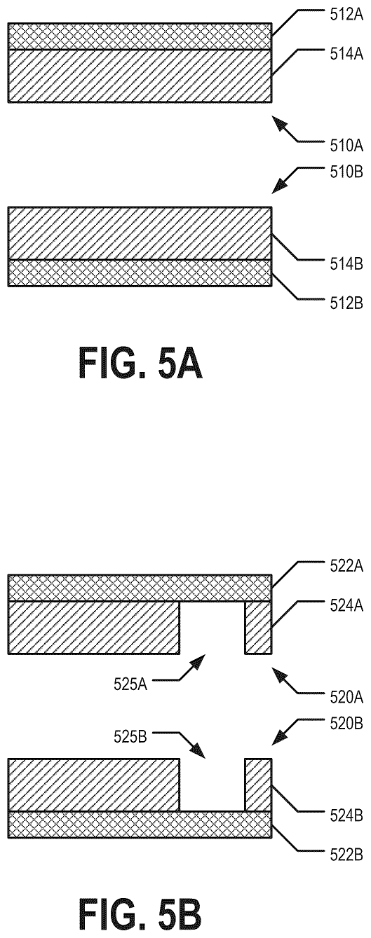

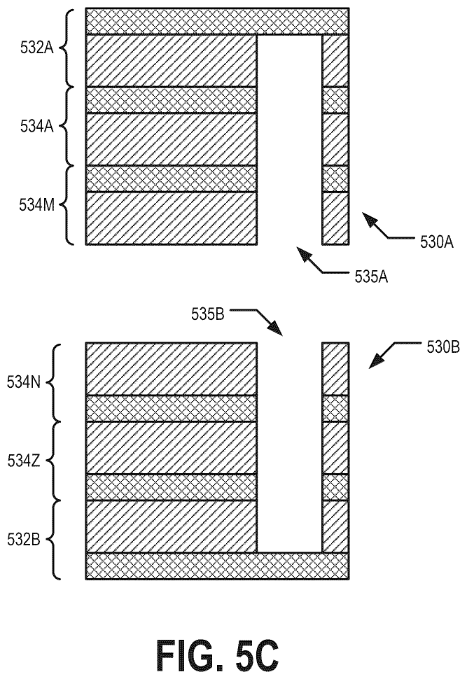

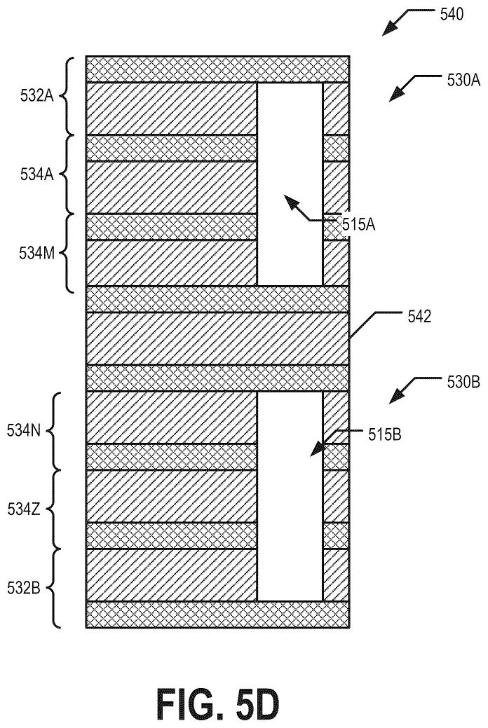

FIG. 5 provides a flowchart illustrating various processes and/or procedures for fabricating a circuit board substrate containing one or more air voids. FIGS. 5A-5D provide partial cross-section views of various stages of fabricating a circuit board substrate containing a pair of aligned air voids.

Starting at block 502, individual layers of the circuit board substrate are prepared. For example, as shown in FIG. 5A, the individual layers of the circuit board substrate 510A, 510B each include a copper sub-layer 512A, 512B and a prepreg and/or dielectric sub-layer 514A, 514B. The copper sub-layers 512A, 512B include conductive pathways and/or traces of various circuits of the circuit board and the prepreg and/or dielectric sub-layers are configured to electrically and physically separate adjacent copper sub-layers. In some embodiments, preparing the individual layers of the circuit board include laminating a copper foil to the prepared and/or dielectric sub-layer and patterning the copper foil to form the copper sub-layer having desired conductive pathways and/or traces defined therein.

Returning to FIG. 5, at block 504, holes are drilled through respective layers using laser drilling, for example. In some embodiments, as shown in FIG. 5B, the copper sub-layers 522A, 522B of air void edge layers 520A, 520B are used as laser stopper layers when etching cavities 525A, 525B through the prepreg and/or dielectric layers 524A, 524B of the air void edge layers 520A, 520B. For air void layers (e.g., layers of the circuit board substrate configured to have the air void pass therethrough) that are not air void edge layers, laser drilling may be used to form a through hole through the entire layer. In various embodiments, the (x, y) coordinates (in a plane parallel to the surface of a layer) are provided as input to the operating and/or controlling software configured to control the laser drilling machine used to drill the cavities and/or through holes. For example, the laser drilling machine may be a computer numeric controlled (CNC) laser drilling machine configured to precise laser drilling. In various embodiments, the input provided to the operating and/or controlling software configured to control the laser drilling machine are configured to control the location and the size of the drilled cavities and/or through holes.

Continuing with FIG. 5, at block 506, the air void layers of the circuit board substrate are sequentially laminated together. For example, FIG. 5C illustrates a first substrate portion 530A that has been formed by sequentially laminating air void through layers 534A-534M onto air void edge layer 532A such that the walls or edges of the respective holes and/or openings 535A through each of the air void through layers 534A-534M and the cavity in air void edge layer 532A are aligned. Similarly, a second substrate portion 530B may be formed by sequentially laminating air void through layers 534N-534Z onto air void edge layer 532B such that the walls or edges of the respective holes and/or openings 535B through each of the air void through layers 534N-534Z and the cavity in air void edge layer 532B are aligned.

Returning to FIG. 5, at block 508, the full circuit board substrate is laminated together. FIG. 5D illustrates an example circuit board substrate 540 formed by laminating the first substrate portion 530A, one or more void-free layers 542, and the second substrate portion 530B together. Laminating the first substrate portion 530A, one or more void-free layers 542, and the second substrate portion 530B together provides the full circuit board substrate 540 having air voids 515A, 515B formed therein.

### Example Datacenter

In various embodiments, a system includes one or more circuit boards having connection finger pads configured to provide a high-speed communication channel between a connector pin and components of the circuit board. In various embodiments, such circuit boards include air voids within one or more dielectric layers of the circuit boards. For example, the circuit board may be a PCB hosting a PCIe component, such as a PCIe switch and/or the like.

Datacenters may include multiple network switches in a particular topology, such as a fat tree topology, a slim fly topology, a dragonfly topology, and/or the like. The specifications and makeup of the network switches in the topology affects the overall network performance (e.g., bandwidth capability) of the datacenter.

Datacenters are the storage and data processing hubs of the internet. The massive deployment of cloud applications is causing datacenters to expand exponentially in size, stimulating the development of faster switches than can cope with the increasing data traffic inside the datacenter. Current state-of-the-art switches are capable of handling 12.8 Tb/s of traffic by employing electrical switches in the form of application specific integrated circuits (ASICs) equipped with 256 data lanes, each operating at 50 Gbps. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

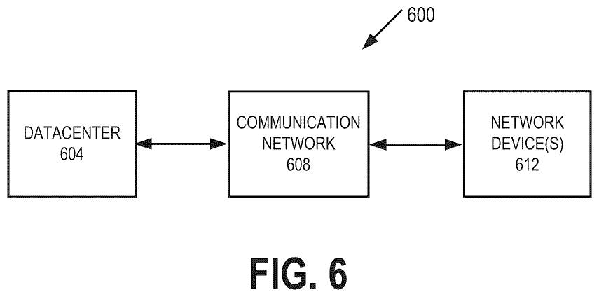

FIG. 6 illustrates a system 600 according to at least one example embodiment. The system 600 includes a datacenter 604, a communication network 608, and one or more network devices 612. In at least one example embodiment, the datacenter 604 corresponds to a collection of network devices, such as network switches (e.g., Ethernet switches) connected with a collection of servers or compute nodes. The datacenter 604 may adhere to a networking topology (e.g., a hierarchal networking topology), such as a fat tree topology, a Slim Fly topology, a Dragonfly topology, and/or the like. The datacenter 604 routes traffic amongst the network switches and servers therein, and at least one layer of the topology in the datacenter 604 is coupled to the communication network 608 to allow networking traffic to flow between the datacenter 604 and the network device(s) 612.

Examples of the communication network 608 that may be used to connect the datacenter 604 and the network device(s) 612 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The one or more network devices 612 may include switch, router, or Network Interface Controller (NIC), interconnect using ports, one or more of Personal Computer (PC), a laptop, a tablet, a smartphone, a server, a collection of servers, and/or any suitable computing device for sending and receiving signals over the communication network 608. In at least one example embodiment, the one or more network devices 612 correspond to another datacenter, similar to or the same as datacenter 604.

As noted above, the datacenter 604 and/or the network device(s) 612 may include storage devices and/or processing circuitry for carrying out computing tasks, for example, tasks associated with controlling the flow of data internally and/or over the communication network 608. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory).

Additionally or alternatively, the processing circuitry may comprise hardware, such as an application specific integrated circuit (ASIC). For example, the processor may be or include one or more of an Integrated Circuit (IC) chip, a microprocessor, a Central Processing Unit (CPU), a Graphics Processing Unit (GPU), a Data Processing Unit (DPU), a Field Programmable Gate Array (FPGA), a network interface controller (NIC), an ASIC, combinations thereof, and the like. The processing circuitry may comprise an ASIC and/or may be capable of performing as a central processing unit (CPU), a graphics processing unit (GPU), a network interface controller (NIC), a data processing unit (DPU), or any other computing device in which with data is received and/or transmitted.

Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the datacenter 604 and network device(s) 612 may include one or more communication interfaces for facilitating wired and/or wireless communication between one another and other unillustrated elements of the system 600.

In related art systems, a fat tree topology may use the same electrical switching devices on all layers (edge, aggregation, core). For example, each switching device may be 1 U switch, where 1 U refers to the industry standard size for rack-mounted switch and/or server. The interconnection between switches of different layers may be accomplished with optical links or optical interconnects using active optical cables and optical transceivers implemented in a pluggable form factor (also referred to as “pluggables”).

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

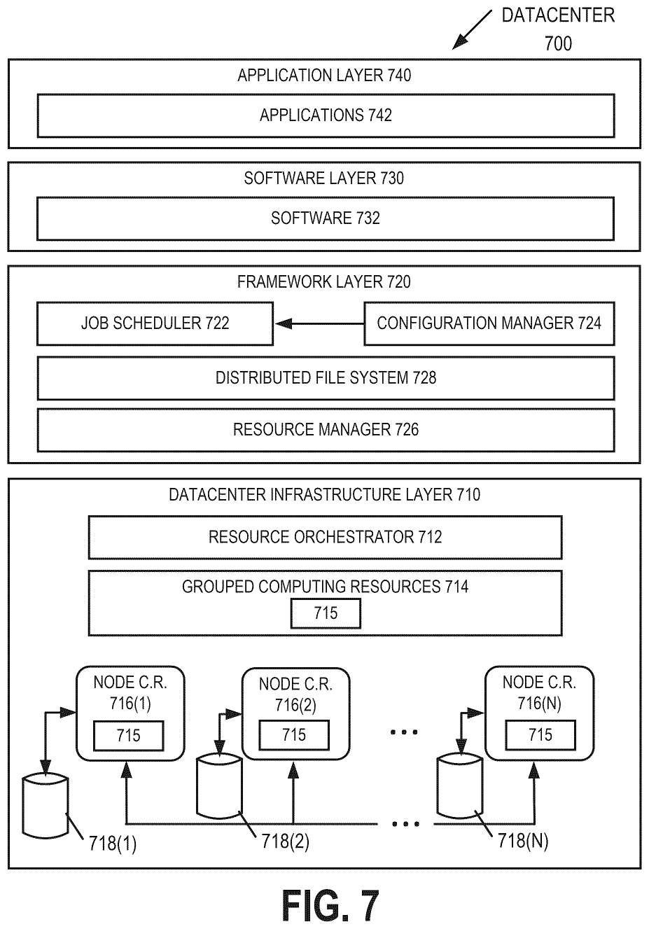

FIG. 7 illustrates an example datacenter 700, in which at least one embodiment may be used. In at least one embodiment, datacenter 700 includes a datacenter infrastructure layer 710, a framework layer 720, a software layer 730, and an application layer 740.

In at least one embodiment, as shown in FIG. 7, datacenter infrastructure layer 710 may include a resource orchestrator 712, grouped computing resources 714, and node computing resources (“node C.R. s”) 716(1)-716(N), where “N” represents a positive integer (which may be a different integer “N” than used in other figures). In at least one embodiment, node C.R. s 716(1)-716(N) may include, but are not limited to, any number of central processing units (“CPUs”) or other processors (including accelerators, field programmable gate arrays (FPGAs), graphics processors, etc.), memory storage devices 718(1)-718(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R. s 716(1)-716(N) may be a server having one or more of above-mentioned computing resources.

In at least one embodiment, grouped computing resources 714 may include separate groupings of node C.R. s housed within one or more racks (not shown), or many racks housed in datacenters at various geographical locations (also not shown). In at least one embodiment, separate groupings of node C.R. s within grouped computing resources 714 may include grouped compute, network, memory, or storage resources that may be configured or allocated to support one or more workloads. In at least one embodiment, several node C.R. s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 712 may configure or otherwise control one or more node C.R. s 716(1)-716(N) and/or grouped computing resources 714. In at least one embodiment, resource orchestrator 712 may include a software design infrastructure (“SDI”) management entity for datacenter 700. In at least one embodiment, resource orchestrator 712 may include hardware, software or some combination thereof.

In at least one embodiment, as shown in FIG. 7, framework layer 720 includes a job scheduler 722, a configuration manager 724, a resource manager 726 and a distributed file system 728. In at least one embodiment, framework layer 720 may include a framework to support software 732 of software layer 730 and/or one or more application(s) 742 of application layer 740. In at least one embodiment, software 732 or application(s) 742 may respectively include web-based service software or applications, such as those provided by Amazon Web Services, Google Cloud and Microsoft Azure. In at least one embodiment, framework layer 720 may be, but is not limited to, a type of free and open-source software web application framework such as Apache Spark™ (hereinafter “Spark”) that may utilize distributed file system 728 for large-scale data processing (e.g., “big data”). In at least one embodiment, job scheduler 722 may include a Spark driver to facilitate scheduling of workloads supported by various layers of datacenter 700. In at least one embodiment, configuration manager 724 may be capable of configuring different layers such as software layer 730 and framework layer 720 including Spark and distributed file system 728 for supporting large-scale data processing. In at least one embodiment, resource manager 726 may be capable of managing clustered or grouped computing resources mapped to or allocated for support of distributed file system 728 and job scheduler 722. In at least one embodiment, clustered or grouped computing resources may include grouped computing resources 714 at datacenter infrastructure layer 710. In at least one embodiment, resource manager 726 may coordinate with resource orchestrator 712 to manage these mapped or allocated computing resources.

In at least one embodiment, software 732 included in software layer 730 may include software used by at least portions of node C.R.s 716(1)-716(N), grouped computing resources 714, and/or distributed file system 728 of framework layer 720. In at least one embodiment, one or more types of software may include, but are not limited to, Internet web page search software, e-mail virus scan software, database software, and streaming video content software.

In at least one embodiment, application(s) 742 included in application layer 740 may include one or more types of applications used by at least portions of node C.R.s 716(1)-716(N), grouped computing resources 714, and/or distributed file system 728 of framework layer 720. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 724, resource manager 726, and resource orchestrator 712 may implement any number and type of self-modifying actions based on any amount and type of data acquired in any technically feasible fashion. In at least one embodiment, self-modifying actions may relieve a datacenter operator of datacenter 700 from making possibly bad configuration decisions and possibly avoiding underutilized and/or poor performing portions of a datacenter.

In at least one embodiment, datacenter 700 may include tools, services, software, or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 700. In at least one embodiment, trained machine learning models corresponding to one or more neural networks may be used to infer or predict information using resources described above with respect to datacenter 700 by using weight parameters calculated through one or more training techniques described herein.

In at least one embodiment, datacenter may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 715 are used to perform inferencing and/or training operations associated with one or more embodiments. In at least one embodiment, inference, and/or training logic 715 may be used in system FIG. 7 for inferencing or predicting operations based, at least in part, on weight parameters calculated using neural network training operations, neural network functions and/or architectures, or neural network use cases described herein.

### Example System Use Case

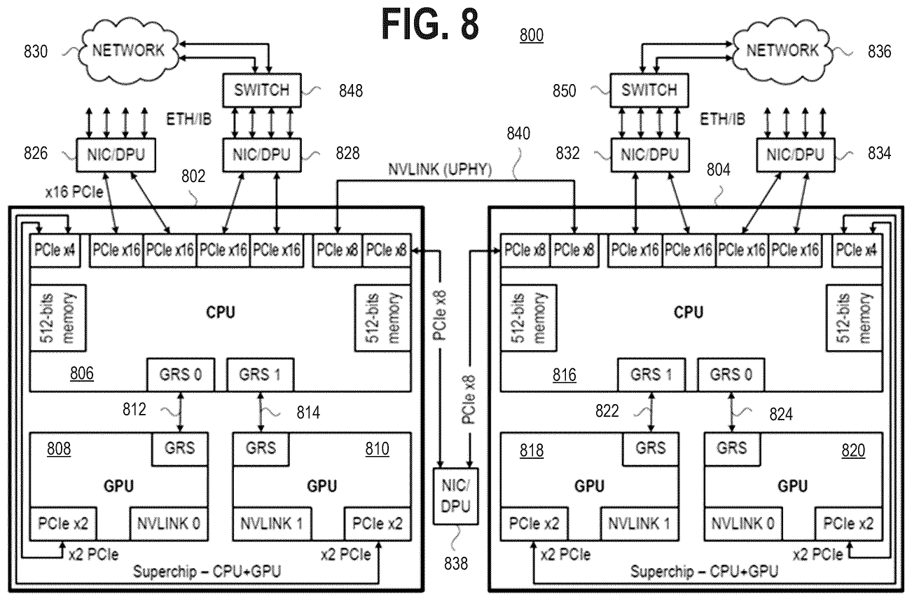

FIG. 8 is a block diagram that schematically illustrates a computing system 800, e.g., a data center or a High-Performance Computing (HPC) cluster, in accordance with an embodiment that is described herein. System 800 comprises a plurality of subsystems, e.g., multiple processing devices coupled to each other, multiple network devices, and multiple networks, according to at least one embodiment. Computing system 800 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 800 and to one or more external networks 830, 836. In the present example, system 800 comprises a packet switch 848 that connects NIC/DPU 828 to network 830, and a packet switch 850 that connects NIC/DPU 832 to network 836.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 800 can include one or more CPUs and one or more GPUs.

FIG. 8 also demonstrates an example architecture of a multi-GPU architecture. As illustrated in the figure, computing system 800 includes a processing device 802 with a multi-GPU architecture. In particular, processing device 802 may be a system-on-chip and includes multiple subsystems such as a CPU 806, a GPU 808, and a GPU 810. CPU 806 can be coupled to GPU 808 via a die-to-die (D2D) or chip-to-chip (C2C) interconnect 812, such as a Ground-Referenced Signaling interconnect (GRS interconnect). CPU 806 can be coupled to GPU 810 via a D2D or C2C interconnect 814. CPU 806 can also couple to GPU 808 and GPU 810 via PCIe interconnects.

CPU 806 can be coupled to one or more NICs or DPUs, which are coupled to one or more networks. For example, as illustrated in FIG. 3, CPU 806 is coupled to a first NIC/DPU 826, which is coupled to a network 830. CPU 806 is also coupled to a second NIC/DPU 828, which is coupled to network 830 via switch 848. NIC/DPU 826 and NIC/DPU 828 can be coupled to network 830 over Ethernet (ETH), NVLINK or InfiniBand (IB) connections, for example.

Computing system 800 also includes a processing device 804 with a multi-GPU architecture. In particular, processing device 804 includes multiple subsystems including a CPU 816, a GPU 818, and a GPU 820. CPU 816 can be coupled to GPU 818 via an D2D or C2C interconnect 822. CPU 816 can be coupled to GPU 820 via a D2D or C2C interconnect 824. CPU 816 can also couple to GPU 818 and GPU 820 via PCIe interconnects. CPU 816 can be coupled to one or more NICs or DPUs, which are coupled to one or more networks. For example, as illustrated in FIG. 3, CPU 816 is coupled to a first NIC/DPU 832, which is coupled to a network 836. CPU 816 is also coupled to a second NIC/DPU 834, which is coupled to network 836 via switch 850. NIC/DPU 832 and NIC/DPU 834 can be coupled to network 836 over Ethernet (ETH), NVLINK or InfiniBand (IB) connections.

In at least one embodiment, processing device 802 and processing device 804 can communication with each other via a NIC/DPU 838, such as over PCIe interconnects. Processing device 802 and processing device 804 can also communicate with each other over a high-bandwidth communication interconnects 840, such as an NVLink interconnect or other high-speed interconnects. The packet switches in FIG. 3 may comprise, for example, Nvidia Quantum-2 switches. The NICs/DPUs in the figure may comprise, for example, Nvidia Bluefield DPUs.

In various embodiments, one or more of the interconnects 812, 814, 822, 824 may be optical interconnects disclosed herein. Additionally, in various embodiments, switches 848, 850 may be in communication with NIC/DPU 828, 832, respectively, via one or more optical interconnects disclosed herein. In some embodiments, NIC/DPU 826, 834 may be in communication with one or more additional elements via optical interconnects disclosed herein. For example, various elements of the computing system 800 may be in communication with one another via one or more optical interconnects disclosed herein.

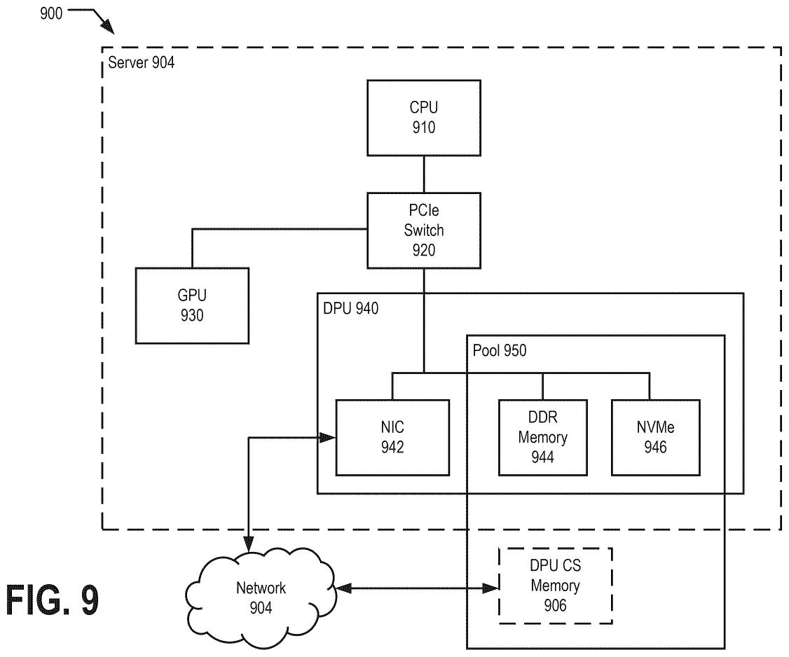

FIG. 9 illustrates an example computing environment 900 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 900 may include a server 902 which may be used to perform high performance computing (HPC) workloads, such as AI training or machine learning model training. In an embodiment, the server 902 may be an application instance or a compute node. The server 902 may include a CPU 910 associated with a switch 920, such as a peripheral component interconnect express (PCIe) switch, which may control at least some data transmission over communication paths interconnecting various components. In an embodiment, the CPU 910 may include a root complex processor.

The PCIe switch 920 may also be associated with a GPU 930 and a DPU 940, and may transmit data between at least some of the CPU 910, the GPU 930, the DPU 940, and other components (e.g., via one or more optical interconnects disclosed herein). In an embodiment, the PCIe switch 920 may be associated with more than one GPU or more than one DPU. In another embodiment, the PCIe switch 920 may be located within the DPU 940. The PCIe switch 920 may manage the transfer of at least some data between the CPU 910, the GPU 930, and the DPU 940. In another embodiment, the number of GPUs associated with the PCIe switch 920 may be equal to the number of DPUs associated with the PCIe switch 920. In at least one embodiment, the server 902 may include, without limitation, any number of the CPUs 910, the PCIe switches 920, the GPUs 930, and/or the DPUs 940, in any combination. For example, in at least one embodiment, server 902 could include eight, sixteen, thirty-two, and/or more GPUs 930. In at least one embodiment, communication paths interconnecting various components, including but not limited to the CPU 910, the PCIe switch 920, the GPU 930, and the DPU 940, in FIG. 9 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 940 may include a network interface controller (NIC) 942, a DDR memory 944, and a non-volatile memory express (NVMe) device 946. The NIC 942 may be able to interface with a network 904, which may also interface with additional NVMe devices available to the DPU 940, such as over fabric. In an embodiment, the DPU 940 may not include the NVMe device 946. In another embodiment, the NVMe device 946 may be located on the server 902 and not on the DPU 940. In yet another embodiment, the computing environment 900 may include more than one of the NVMe device 946, such as a first NVMe device in the DPU 940 and a second first NVMe device on the server 902 an associated directly with the PCIe switch 920. In an embodiment, the DPU 940 may not include the DDR memory 944 and may include a computational storage services (CSS) in place of, or in addition to, the DDR memory 944. For example, computing environment 900 may include DPU computational storage (CS) memory 906 available to the DPU 940 as part of the CSS. The network 904 may be able to interface with the DPU CS memory 906 through the NIC 942, according to any suitable interface protocol, such as remote direct memory access (RDMA) over Ethernet, InfiniBand, Fiber Channel, etc.

The total memory of the computing environment 900 available for data storage may be expanded through the use of the DPU 940 on nodes of the system. The DPU 940 may have access to a pool 950 of memory already available to the server 902, such as double data rate (DDR) memory, on-board NVMe devices, NVMe devices over fabric, and CS. The pool 950 of memory may include at least one of the DDR memory 944, NVMe 946, and the DPU CS memory 906. The DPU 940 may also be able to access the available memory of other DPUs as part of the pool 950, and other DPUs may be able to access the available memory of DPU 940, such as the pool 950. This available memory can be accessed and utilized for data storage, without the addition of compute resources, such as compute nodes, which would be required using other solutions. The available pool 950 accessible to the DPU 940 may be provisioned for the server 902 to expand the total memory available for data storage, such as to reduce the data storage load on the CPU 910 or the GPU 930, which can instead increase the utilization of their memory for processing. For example, during training of an AI, the model states, residual states, activation functions, and checkpoints can be stored, or offloaded, on the pool 950 accessible to the DPU 940.

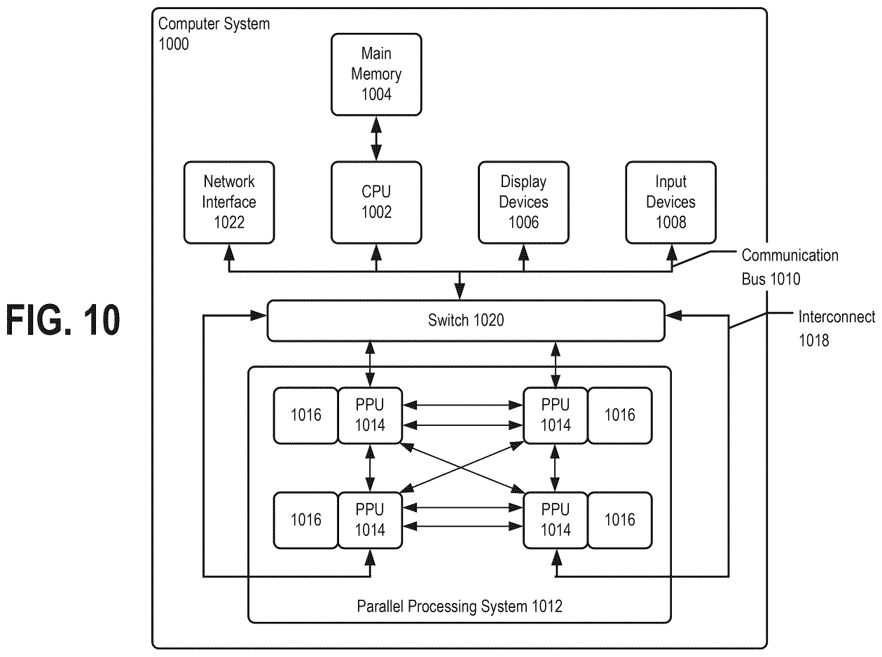

FIG. 10 illustrates a computer system 1000, according to at least one embodiment. In at least one embodiment, computer system 1000 comprises at least one optical interconnect of an example embodiment.

In at least one embodiment, computer system 1000 comprises, without limitation, at least one central processing unit (“CPU”) 1002 that is connected to a communication bus 1010 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1000 includes, without limitation, a main memory 1004 and control logic (e.g., implemented as hardware, software, or a combination thereof) and data are stored in main memory 1004 which may take form of random access memory (“RAM”). In at least one embodiment, a network interface subsystem (“network interface”) 1022 provides an interface to other computing devices and networks for receiving data from and transmitting data to other systems from computer system 1000.

In at least one embodiment, computer system 1000, in at least one embodiment, includes, without limitation, input devices 1008, parallel processing system 1012, and display devices 1006 which can be implemented using a conventional cathode ray tube (“CRT”), liquid crystal display (“LCD”), light emitting diode (“LED”), plasma display, or other suitable display technologies. In at least one embodiment, user input is received from input devices 1008 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 1004 and/or secondary storage. Computer programs, if executed by one or more processors, enable system 1000 to perform various functions in accordance with at least one embodiment. memory 1004, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 1002; parallel processing system 1012; an integrated circuit capable of at least a portion of capabilities of both CPU 1002; parallel processing system 1012; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 1000 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1012 includes, without limitation, a plurality of parallel processing units (“PPUs”) 1014 and associated memories 1016. In at least one embodiment, PPUs 1014 are connected to a host processor or other peripheral devices via an interconnect 1018 and a switch 1020 or multiplexer. In at least one embodiment, parallel processing system 1012 distributes computational tasks across PPUs 1014 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 1014, although such shared memory may incur performance penalties relative to use of local memory and registers resident to a PPU 1014. In at least one embodiment, operation of PPUs 1014 is synchronized through use of a command such as_syncthreads( ), wherein all threads in a block (e.g., executed across multiple PPUs 1014) to reach a certain point of execution of code before proceeding.

The PPUs 1014 may be in communication with one another and/or switch 1020 via one or more optical interconnects in accordance with example embodiments disclosed herein.

Some embodiments of the present disclosure are directed to a multi-chip module (MCM) with a centrally positioned main die and a plurality of peripherally positioned MCM sockets configured to mechanically receive and electrically connect mezzanine packages, which may include co-packaged optics (CPO) packages and co-packaged copper (CPC) packages. Each mezzanine package may include a package substrate including a connector portion that is configured to engage the MCM socket and a main portion extending beyond the periphery of the MCM substrate. The main portion of the mezzanine package may be configured to receive optical devices and/or integrated circuits, such as via mezzanine sockets, to allow connections to be made between the optical devices and/or integrated circuits/RF copper cable connectors and the main die of the MCM. Due to the extension of the mezzanine package beyond the periphery of the MCM substrate, the physical size of the MCM substrate may remain small to reduce cost and avoid the previously discussed production challenges, while allowing connections to a number of optical devices and integrated circuits via the mezzanine packages, which occupy the relatively inexpensive space around the periphery of the MCM substrate. As used herein, the terms “co-packaged optic” (or “CPO”) and “co-packaged copper” (or “CPC”) may refer to an advanced heterogeneous integration of either optics and silicon or copper and silicon, in which either integration may be implemented on a single packaged substrate. The CPO may utilize pluggable optical modules that include an optical engine (OE) to convert optical signals to electrical signals and electrical signals to optical signals. The CPO may further be comprised of an optical component on a photonics die and an electrical component on an electrical die.

As used herein, a ball grid array (BGA) may be a type of surface-mount packaging used for integrated circuits. BGA packages use an array of metallic conductor balls arranged in a grid to permanently mount devices such as microprocessors on a PCB. The metallic conductor balls may then undergo the reflow process described above, wherein the metallic conductor balls may be preheated, then melted to bond the IC to a substrate to form an IC package.

As used herein, the term “flip chip (FC)” may refer to a method for interconnecting dies, such as semiconductor devices, IC chips, integrated passive devices, and microelectromechanical systems (MEMS), to external circuitry with solder bumps that have been deposited onto chip pads. The solder bumps may be deposited onto chip pads on the top side of the wafer during final wafer processing. The chip may be mounted to external circuitry (such as a circuit board or another chip or wafer) by “flipping” the chip, such that the chip's top side faces down and is positioned to allow the pads of the chip to align with matching pads on the external circuit. Solder is reflowed to complete the interconnect.

The medium of transmission is any type of networking cable e.g., direct attach copper (DAC), active copper cable (ACC), active optical cables (AOCs), cable assembly with octal small form-factor pluggable (OSFP) connectors or the like) or interconnect utilized by datacenter racks and associated switch modules (e.g., a Small Form Pluggable (SFP), quad small form-factor pluggable (QSFP), or the like). It may also be a passive copper cable (PCC), an active optical cable, and an active optical module for transmitting optical signals. In other alternative cases, the cable may also include an Ethernet cable, active optical cables (AOCs) or cable assembly with OSFP connectors. The semiconductor device may be a pluggable network interface device may comprise the male end portion of a direct attach cable assembly (DAC). The network connectors may each be configured to connect to a networking device of any type (e.g., QSFP, Direct Attach Copper, active optical cables (AOC), etc.), and may thus be dimensioned (e.g., sized and shaped) to mate with or otherwise connect to any corresponding networking device. The cable connector may be of any type (e.g., an AOC connector, Ethernet connector, Direct Attach Copper connector, Active Optical Module, or the like). A PCB is used to electrically connect electronic components using conductive pathways, or traces, etched from metal sheets. In many electronic systems, one or more very large-scale integrated circuit (“VLSI”) components is coupled to a host system printed circuit board (“PCB”). Such VLSI components may include, for example, central processing unit (“CPU) devices and graphics processing unit (“GPU”) devices. The PCB may hold at least one processing circuitry. The processing circuitry may comprise hardware, such as an application specific integrated circuit (ASIC). The processing circuitry may comprise an ASIC and/or may be capable of performing as a central processing unit (CPU), a graphics processing unit (GPU), a network interface controller (NIC), a data processing unit (DPU), or any other computing device in which with data is received and/or transmitted. Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. It should be appreciated that any appropriate type of electrical or optical component or collection of electrical or optical components may be suitable for inclusion in the processing circuitry. Numerous example embodiments will be described below in which a semiconductor package is mounted within a through hole of a PCB. Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, the PCB to which the semiconductor package is mounted may comprise an add-in card, such as a PCIe card, that is configured to be coupled to a system board or motherboard of a host system. In other embodiments, the PCB to which the semiconductor package is mounted may be the system board or motherboard of the host system itself. Moreover, the system board or the motherboard may be associated with any type of host system. For example, the PCB may comprise the system board in a multi-node rack-mounted server in a data center, or it may comprise the motherboard of a workstation, desktop, laptop, or mobile device. Other embodiments are also possible.

### Conclusion

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A circuit board comprising:
a circuit board substrate; and
a connection finger pad disposed on a first surface of the circuit board substrate,
wherein an air void is disposed within the circuit board substrate that is aligned with at least a portion of the connection finger pad.

2. The circuit board of claim 1, wherein the circuit board comprises a dielectric layer and the air void is disposed within the dielectric layer.

3. The circuit board of claim 1, wherein the connection finger pad is characterized by a finger length that is at least as long as a wipe length of the connection finger pad, and the air void has a void length that is within half a millimeter of the wipe length.

4. The circuit board of claim 3, wherein the void length is substantially equal to the wipe length.

5. The circuit board of claim 3, wherein the void length is substantially equal to half the finger length.

6. The circuit board of claim 1, wherein the connection finger pad is characterized by a finger width and the air void is characterized by a void width and the finger width is substantially equal to the void width.

7. The circuit board of claim 1, wherein the air void is characterized by a void height and the void height is greater than zero and no more than 0.8 mm.

8. The circuit board of claim 6, wherein the void height is at least 0.4 mm.

9. The circuit board of claim 1, further comprising a conductive element disposed on a second surface of the circuit board substrate, the first surface opposite the second surface, and the air void is disposed between the connection finger pad and the conductive element.

10. The circuit board of claim 1, wherein the connection finger pad is one of a plurality of connection finger pads and the air void is one of a plurality of air voids and respective air voids are aligned with respective connection finger pads.

11. The circuit board of claim 9, wherein each of the plurality of connection finger pads is configured for communicating electrical signals characterized by frequencies of at least 100 MHz.

12. The circuit board of claim 10 further comprising one or more conductive pads configured for communicating electrical signals characterized by frequencies less than 100 MHz.

13. The circuit board of claim 1, wherein the air void is a first air void and the circuit board further comprises a second air void, the first air void and the second air void aligned with one another between the first surface and a second surface of the circuit board.

14. A networking card comprising:
a circuit board having a plug-in finger edge interface comprising one or more connection finger pads formed on a circuit board substrate of the circuit board, wherein one or more air voids are disposed within the circuit board substrate and are each aligned with at least a portion of a respective connection finger pad of the one or more connection finger pads.

15. A method comprising:
fabricating a circuit board substrate such that the circuit board substrate comprises an air void within the circuit board substrate; and
patterning a conductive material on a first surface of the circuit board substrate to form a connection finger pad that is aligned with the air void.

16. The method of claim 15, wherein fabricating the circuit board substrate comprises:
preparing a plurality of individual layers of the substrate, the plurality of individual layers comprising at least one air void layer and at least one void-free layer; and
drilling a cavity or a hole in each of the air void layer of the plurality of individual layers.

17. The method of the claim 16, wherein the cavity or hole is drilled using laser drilling.

18. The method of claim 17, wherein each of the plurality of individual layers comprise respective copper sub-layers and dielectric sub-layers and a copper sub-layer of an air void edge layer is used as a laser stopper layer during the laser drilling.

19. The method of claim 16, wherein fabricating the circuit board substrate further comprises sequentially laminating air void layers of the plurality of individual layers to form one or more substrate portions having respective openings formed therein.

20. The method of claim 19, wherein fabricating the circuit board substrate further comprises laminating the one or more substrate portions and the at least one void-free layer to form the circuit board substrate having one or more air voids defined therein.
